(19) United States
(12) Patent Application Publication
(10) Pub. No.: US 2025/0372414 A1
(43) Pub. Date: Dec. 4, 2025

(54) HEAT TREATMENT SYSTEM AND STATE MONITORING METHOD

(71) Applicant: Tokyo Electron Limited, Tokyo (JP)

(72) Inventor: Moriyoshi KINOSHITA, Iwate (JP)

(21) Appl. No.: 19/211,727

(22) Filed: May 19, 2025

(30) Foreign Application Priority Data
May 30, 2024 (JP) 2024-088068

(51) Int. Cl. H01L 21/67; B25J 9/16; H01L 21/677

(52) U.S. Cl. CPC H01L 21/67098; B25J 9/1694; H01L 21/67265; H01L 21/67748; H01L 21/67751

(57) ABSTRACT

A heat treatment system heat treats a plurality of substrates. The heat treatment system includes a substrate holder that holds the plurality of substrates, a transfer device provided in a loading region where the substrate holder waits and transfers the plurality of substrates to the substrate holder, a control unit that controls an operation of the transfer device, and a reference member installed within a movement range of the transfer device in the loading region. The transfer device includes a guide body moving parallel to a longitudinal direction of the substrate holder, and a detection sensor detecting the reference member. The control unit moves the transfer device relative to the reference member and recognizes a state of the guide body based on detection of the reference member by the detection sensor.

### CROSS-REFERENCE TO RELATED APPLICATIONS

This application is based on and claims priority from Japanese Patent Application No. 2024-088068, filed on May 30, 2024, with the Japan Patent Office, the disclosure of which is incorporated herein in its entirety by reference.

### TECHNICAL FIELD

The present disclosure relates to a heat treatment system and a state monitoring method.

### BACKGROUND

Japanese Patent Laid-open Publication No. 2005-277175 discloses a heat treatment system (e.g., a heat treatment apparatus) in which a wafer boat (e.g., a wafer holder) holding a plurality of substrates (e.g., wafers) is loaded into a processing chamber and heat treatment is performed on the respective substrates. In the heat treatment system, a waiting position for the wafer boat is provided at a lower portion of the processing chamber, and a transfer device (e.g., a transfer mechanism) is provided to transfer the substrates from the wafer boat.

The transfer device has an elevating arm that may vertically move by, for example, a ball screw, and a base that may horizontally rotate the elevating arm. In addition, the transfer device is capable of advancing and retreating a substrate support, such as a fork, from the elevating arm.

### SUMMARY

According to an aspect of the present disclosure, a heat treatment system includes a substrate holder that holds a plurality of substrates, a transfer device that is provided in a loading region where the substrate holder waits, and transfers the substrates to the substrate holder, a control unit that controls an operation of the transfer device, and a reference member installed within a movement range of the transfer device in the loading region. The transfer device includes a guide body that moves in parallel with a longitudinal direction of the substrate holder, and a detection sensor that detects the reference member. The control unit is configured to move the transfer device relative to the reference member and recognize a state of the guide body based on detection of the reference member by the detection sensor.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a side view schematically illustrating the entire configuration of a heat treatment system according to an embodiment.

FIG. 2 is a side cross-sectional view schematically illustrating an example of a heat treatment apparatus in a heat treatment system.

FIG. 3 is a perspective view illustrating an example of a transfer device in a loading region.

FIG. 4A is a side view illustrating an undeformed guide body in a transfer device, and FIG. 4B is a side view illustrating a deformed guide body in a transfer device.

FIG. 5 is a side view illustrating the operations of a reference member and a transfer device.

FIG. 6 is a plan view illustrating an example of the arrangement of a reference member in a loading region.

FIG. 7 is a flowchart illustrating a heat treatment method including a state monitoring method.

FIG. 8A is a diagram illustrating a reference member according to a modified example and a transfer device including an undeformed guide body, and FIG. 8B is a diagram illustrating a reference member according to a modified example and a transfer device including a deformed guide body.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, a mode for carrying out the present disclosure will be described with reference to the drawings. In the drawings, the same components are given the same reference numerals, and redundant descriptions may be omitted.

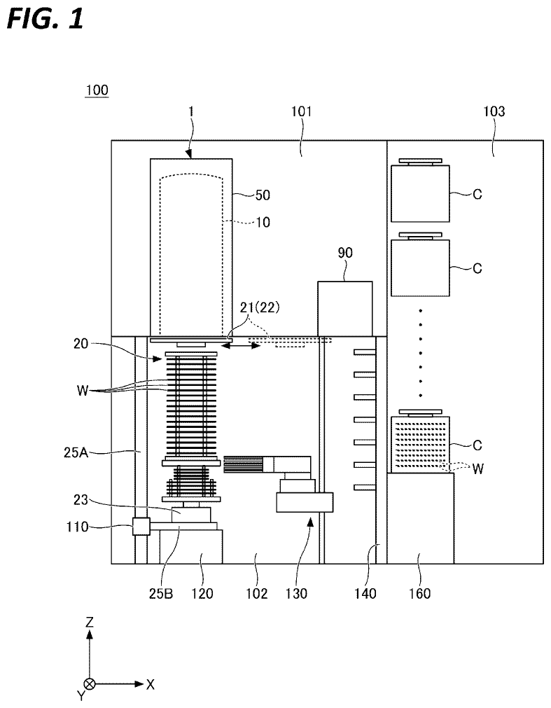

The heat treatment system 100 performs a heat treatment (film formation process) to form a desired film on a surface of each substrate W by heating a plurality of substrates W while supplying a suitable process gas. In order to perform the heat treatment, the heat treatment system 100 includes a plurality of partitioned areas, such as a processing region 101, a loading region 102, and a carrying-in/out region 103, as illustrated in FIG. 1.

The processing region 101 is an area where heat treatment is actually performed on each substrate W, and includes a heat treatment apparatus 1 therein. The loading region 102 is an area where the transfer of each substrate W is performed between the heat treatment apparatus 1 and the carrying-in/out region 103, and has a boat operating unit 110, a boat stage 120, a transfer device 130, and a reference member 140. The carrying-in/out region 103 is an area where a container C such as a front-opening unified pod (FOUP) for accommodating the substrates W is stored and transferred, and has a mounting table 160 where the container C is placed, a storage mechanism (not illustrated) for transferring, waiting, and carrying-in/out a plurality of containers C.

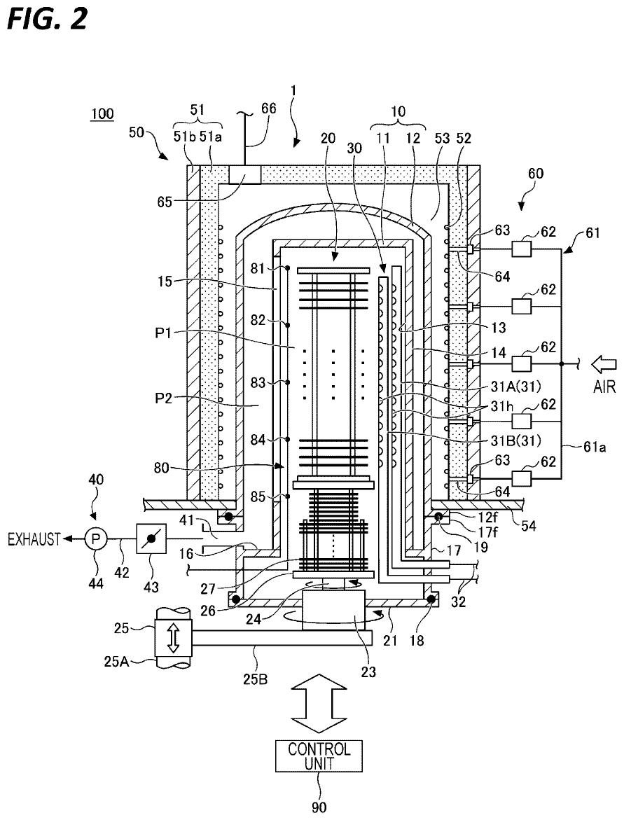

As illustrated in FIG. 2, the heat treatment apparatus 1 is a vertical-type apparatus that maintains the plurality of substrates W arranged in a vertical direction and forms a desired film on the surface of each substrate W by an atomic layer deposition (ALD) method, a chemical vapor deposition (CVD) method, a thermal oxidation method, or any other method. The substrate W on which the film is formed is not particularly limited, and may be, for example, a semiconductor substrate such as a silicon wafer or a compound semiconductor wafer, or a glass substrate.

The heat treatment apparatus 1 includes a processing chamber 10 that accommodates the substrates W and forms films, a gas supply unit 30 that supplies gas into the processing chamber 10, a gas exhaust unit 40 that exhausts gas from the processing chamber 10, and a temperature control furnace 50 that is disposed around the processing chamber 10. In addition, the heat treatment system 100 includes a control unit 90 that controls each component of the system including the heat treatment apparatus 1.

The processing chamber 10 is formed in a cylindrical shape and is installed to have an axis in a vertical direction (up-down direction). In addition, the processing chamber 10 has a double-tube structure composed of an inner tube 11 and an outer tube 12 that accommodates the inner tube 11. The inner tube 11 and the outer tube 12 are formed of a heat-resistant material such as quartz and are arranged coaxially with each other. The processing chamber 10 is not limited to a double-tube structure and may alternatively have a single-tube structure or a multi-tube structure including three or more tubes.

The inner tube 11 has an open bottom while having a ceiling wall at the top. In addition, the inner tube 11 has an inner diameter larger than the diameter of each substrate W. The interior of the inner tube 11 becomes a processing space P1 in which gas is supplied to each accommodated substrate W and a film is formed. An opening 15 is provided at an appropriate circumferential position of the inner tube 11 to discharge gas from the processing space P1 to a gas flowing space P2 between the inner tube 11 and the outer tube 12. The opening 15 may be formed, for example, in the ceiling wall of the inner tube 11.

In addition, the inner tube 11 has an accommodating portion 13 capable of accommodating a gas supply nozzle 31 of the gas supply unit 30 at a circumferential position opposite to the opening 15. For example, the accommodating portion 13 is provided on the inner side of a convex portion 14 formed by protruding a portion of side walls of the inner tube 11 diametrically outward.

The outer tube 12 has an inner diameter larger than that of the inner tube 11 and covers the inner tube 11 in a non-contact manner. The gas flowing space P2 formed on the inner side of the outer tube 12 is continuous along the upper and side portions of the inner tube 11 and allows gas moved from the opening 15 to flow downward in the vertical direction.

The lower end of the processing chamber 10 is supported by a cylindrical manifold 17 formed of stainless steel. The manifold 17 extends across the boundary between the processing region 101 and the loading region 102, and connects the two regions therein. The manifold 17 has a manifold flange 17f at the upper end. The manifold flange 17f fixes and supports an outer tube flange 12f formed at the lower end of the outer tube 12. A sealing member 19 for hermetically sealing the outer tube 12 and the manifold 17 is provided between the outer tube flange 12f and the manifold flange 17f. In addition, the manifold 17 has an annular support plate 16 on the inner wall of an upper portion. The support plate 16 protrudes diametrically inward from the inner wall to fix and support the lower end of the inner tube 11.

A lid 21 is disposed at a lower opening of the manifold 17. The lid 21 is movable in the horizontal and vertical directions by an opening/closing mechanism (not illustrated) and opens/closes the lower opening of the manifold 17 (see also FIG. 1). The lower end of the manifold 17 is provided with a sealing member 18 that hermetically closes the lower opening of the manifold 17 according to the closing operation of the lid 21. The processing chamber 10 and the manifold 17 are brought into an internally sealed state upon closure of the lid 21 after accommodating the wafer boat 20 therein.

The wafer boat 20 is a substrate holder that holds a plurality of substrates W. The longitudinal direction of the wafer boat 20 is along the vertical direction, and the outer edges of the respective substrates W are held by a plurality of shelf plates (not illustrated). In the state where the wafer boat 20 is maintained, the substrates W are arranged at a certain interval in the vertical direction and are supported in the horizontal direction.

In addition, the heat treatment system 100 includes a rotating unit 23 that rotatably supports the wafer boat 20, and a lifting unit 25 that raises and lowers the wafer boat 20 via the rotating unit 23. The rotating unit 23 and the lifting unit 25 constitute the boat operating unit 110 described later in the heat treatment system 100 (see also FIG. 1).

The rotating unit 23 includes a rotating source (not illustrated), a rotating shaft 24 that rotates by the rotating source, and a rotating plate 26 that is connected to the upper end of the rotating shaft 24. The wafer boat 20 is mounted on the upper surface of the rotating plate 26 via a heat insulating structure 27. When the rotating shaft 24 and the rotating plate 26 rotate, the rotating unit 23 enables the heat insulating structure 27 and the wafer boat 20 to rotate around the vertical axis.

The lifting unit 25 includes a column 25A extending in the vertical direction, an arm 25B that may be raised and lowered relatively to the column 25A, and a lifting drive unit (not illustrated) that raises and lowers the arm 25B. The arm 25B extends in a horizontal direction and supports certain members (the wafer boat 20, the rotating plate 26, and the heat insulating structure 27) located above the rotating unit 23. By raising and lowering the arm 25B of the lifting unit 25, the heat treatment apparatus 1 integrally raises and lowers the rotating unit 23 and the members located above the rotating unit 23, thereby inserting and removing the wafer boat 20 into and from the processing chamber 10.

The gas supply unit 30 is equipped with one or more gas supply nozzles 31 to supply gas to each substrate W disposed in the processing space P1. The gas supplied by the gas supply unit 30 may include, for example, a source gas for depositing a precursor on the substrate W, a reaction gas that reacts with the precursor, and a purge gas that purges the processing space P1.

In this embodiment, the gas supply unit 30 has two gas supply nozzles 31 (a first gas supply nozzle 31A and a second gas supply nozzle 31B). The first gas supply nozzle 31A is a nozzle that supplies a source gas and a purge gas into the processing chamber 10. The second gas supply nozzle 31B is a nozzle that supplies a reaction gas into the processing chamber 10. The gas supply unit 30 is not limited to this configuration and may have multiple (e.g., three or more) gas supply nozzles 31 for respective gas types such as a source gas, a reaction gas, and a purge gas. Conversely, the gas supply unit 30 may be configured to supply a source gas, a reaction gas, and a purge gas through a single gas supply nozzle 31.

Each of the gas supply nozzles 31 (the first gas supply nozzle 31A and the second gas supply nozzle 31B) is an injector tube made of quartz and is fixed to the manifold 17. In addition, each gas supply nozzle 31 extends vertically inside the inner tube 11 and is bent into an L-shape at a lower portion to penetrate the inside and outside of the manifold 17. Each gas supply nozzle 31 has a plurality of gas holes 31h at regular vertical intervals inside the inner tube 11 and discharges gas from the respective gas holes 31h in the horizontal direction. The interval between the gas holes 31h is set to be the same as the interval between the substrates W supported on the wafer boat 20, for example. In addition, the vertical position of each of the gas holes 31h is set to be in the middle between the vertically adjacent substrates W. As a result, each of the gas holes 31h may smoothly supply gas to a gap between the substrates W.

The gas supply unit 30 has a plurality of gas supply paths 32, which are respectively connected to the first gas supply nozzle 31A and the second gas supply nozzle 31B, outside the processing chamber 10. The gas supply path 32 connected to the first gas supply nozzle 31A branches off at an intermediate position and is then connected to a source gas source and a purge gas source (not illustrated). The gas supply path 32 connected to the second gas supply nozzle 31B is connected to a reaction gas source (not illustrated). In addition, each gas supply path 32 is provided with, for example, a flow rate controller (not illustrated) for controlling the flow rate of gas, and a valve (not illustrated) for opening/closing a gas flow path at an intermediate position until reaching each gas source (not illustrated).

The gas exhaust unit 40 exhausts gas inside the processing chamber 10 to the outside. The gas supplied through each gas supply nozzle 31 moves from the processing space P1 of the inner tube 11 to the gas flowing space P2 and is then exhausted through a gas outlet 41. The gas outlet 41 is formed above the support plate 16 in the side wall of an upper portion of the manifold 17. The gas outlet 41 is connected to an exhaust path 42 of the gas exhaust unit 40. The gas exhaust unit 40 is provided with a pressure regulating valve 43 and a vacuum pump 44 in the order from the upstream to the downstream of the exhaust path 42. The gas exhaust unit 40 sucks gas inside the processing chamber 10 by the vacuum pump 44 and regulates the flow rate of the exhausted gas by the pressure regulating valve 43, thereby adjusting the pressure inside the processing chamber 10.

Additionally, in the processing chamber 10 (e.g., in the processing space P1 inside the inner tube 11), a temperature sensor 80 is provided to detect the temperature inside the processing chamber 10. The temperature sensor 80 has a plurality of (five in this embodiment) temperature sensing elements 81 to 85 at different positions in the vertical direction. The plurality of temperature sensing elements 81 to 85 may be thermocouples, resistance temperature sensors, or the like. The temperature sensor 80 transmits the temperature detected by each of the temperature sensing elements 81 to 85 to the control unit 90.

Meanwhile, the temperature control furnace 50 completely covers the processing chamber 10 and heats or cools the respective substrates W accommodated in the processing chamber 10 from the outside. Specifically, the temperature control furnace 50 includes a cylindrical housing 51 having a ceiling, and a heater 52 provided on the inside of the housing 51.

The housing 51 is attached to the upper surface of a base plate 54 located at the boundary between the processing chamber 10 and the manifold 17, and heats the processing chamber 10 accommodated therein. The housing 51 is installed at a distance from the processing chamber 10, and forms a temperature control space 53 between the processing chamber 10 and the housing 51.

The housing 51 includes an insulating portion 51a that has the ceiling and covers the entire processing chamber 10, and a reinforcing portion 51b that is located on the outer surface of the insulating portion 51a and reinforces the insulating portion 51a. Additionally, to suppress the thermal influence on temperature control furnace 50 from the outside, the outer surface of the reinforcing portion 51b is covered with a water cooling jacket (not illustrated).

In addition, the temperature control furnace 50 is provided with a cooling unit 60 that circulates a cooling gas such as air into the temperature control space 53 to cool the processing chamber 10 during or after the film formation. The cooling unit 60 includes an external supply path 61 and a flow rate controller 62 both provided outside the temperature control furnace 50, a supply flow path 63 provided in the reinforcing portion 51b, and a plurality of supply holes 64 provided in the insulating portion 51a.

In addition, the cooling unit 60 has an exhaust hole 65 in the ceiling of the housing 51 to discharge air supplied into the temperature control space 53. The exhaust hole 65 is connected to an external exhaust path 66 provided outside the housing 51.

In the above example, the heat treatment apparatus 1 is described as an apparatus that supplies a source gas and a reaction gas as process gases and forms a desired film on the surface of each substrate W. However, the heat treatment system 100 is not limited to applying a film forming apparatus as the heat treatment apparatus 1. For example, the heat treatment system 100 may apply an apparatus of etching a film on the surface of each substrate W or an apparatus of modifying or cleaning the surface of each substrate W, as the heat treatment apparatus. In addition, the heat treatment apparatus may have a configuration that generates plasma inside the processing chamber 10.

The control unit 90 of the heat treatment apparatus 1 may apply a computer including, for example, a processor, a memory, an input/output interface, and a communication interface. The processor is one of a central processing unit (CPU), a graphics processing unit (GPU), an application specific integrated circuit (ASIC), a field-programmable gate array (FPGA), a circuit with a plurality of discrete semiconductors, or a combination thereof. The memory includes, for example, a main memory device including a semiconductor memory, and an auxiliary memory device including a disk or a semiconductor memory (flash memory). The memory may be configured by appropriately combining a volatile memory and a nonvolatile memory (e.g., a compact disk, a digital versatile disk (DVD), a hard disk, or a flash memory).

The memory stores a program for operating the heat treatment system 100 and a recipe such as process conditions for heat treatment. The processor reads and executes the program stored in the memory, thereby controlling each component of the heat treatment system 100. In other words, the control unit 90 of the present disclosure is an electronic circuit having CPU, GPU, ASIC, FPGA, etc., and executes various control operations described herein by executing a command code stored in the memory or by being circuit-designed for a special purpose. The control unit 90 may be implemented by a host computer or a plurality of client computers capable of information communication other through a network. The heat treatment system 100 is not limited to implementation in which each apparatus or device is directly controlled by the control unit 90, and may also be implemented such that it includes a dedicated control device in a certain apparatus or device (e.g., in the transfer device 130) and transmits a control command of the control unit 90 to the control device to control each apparatus or device.

Referring back to FIG. 1, the loading region 102 of the heat treatment system 100 is a space formed under the processing region 101. In the loading region 102, the wafer boat 20 is loaded/unloaded into/from the processing chamber 10, the substrates W are transported within the loading region 102, and the substrates W are transferred to and from the wafer boat 20 or the container C.

In the loading region 102, the boat operating unit 110 is provided under the processing chamber 10 of the heat treatment apparatus 1. The boat operating unit 110 includes, as described above, the rotating unit 23 and the lifting unit 25 (the column 25A and the arm 25B). The lifting unit 25 raises the arm 25B under the operation of the lifting drive unit, thereby loading the entire wafer boat 20 mounted on the arm 25B into the processing chamber 10. In addition, the lifting unit 25 lowers the arm 25B under the operation of the lifting drive unit, thereby unloading the entire wafer boat 20 to a space vertically below the processing chamber 10.

The boat stage 120 allows the wafer boat 20 before or after heat treatment to wait. In the state where the wafer boat 20 and the heat insulating structure 27 (see. e.g., FIG. 2) wait on the boat stage 120, the heat treatment system 100 transfers each substrate W into the wafer boat 20 and removes each substrate W from the wafer boat 20. Although in this embodiment there is one boat stage 120 under the processing chamber 10, the heat treatment system 100 may include a plurality of boat stages 120. For example, the heat treatment system 100 may be configured to transfer the wafer boat 20 between different boat stages 120 by a boat transfer device (not illustrated).

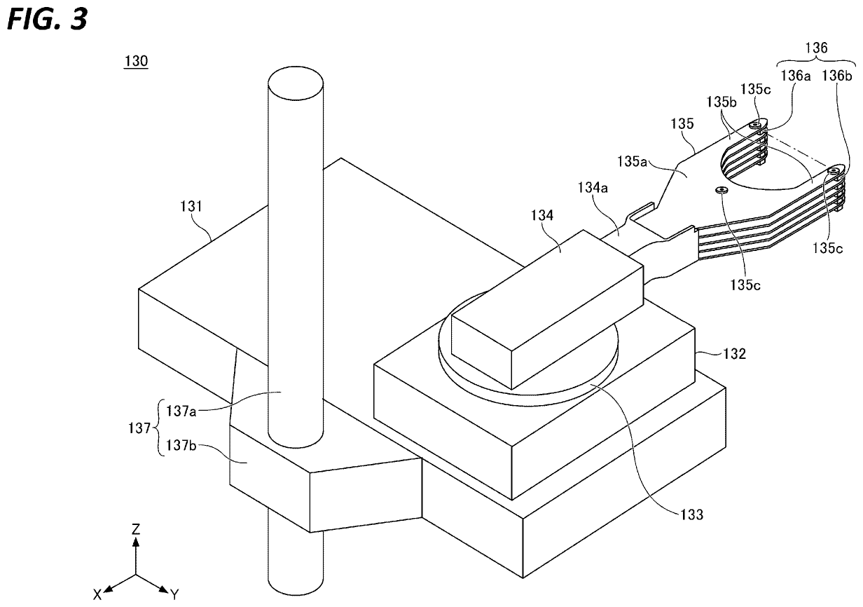

The transfer device 130 is positioned between the boat stage 120 and the carrying-in/out region 103 in the loading region 102 to transfer the substrate W. As illustrated in FIG. 3, the transfer device 130 is configured to be movable in the horizontal direction (X-Y axis direction) and the vertical direction (Z axis direction) and also be rotatable around the vertical axis. For example, the transfer device 130 includes a base 131, a moving body 132 provided on the base 131, a pivot mechanism 133 provided on the moving body 132, an advancing/retreating mechanism 134 provided on the pivot mechanism 133, and a plurality of forks 135 that advance and retreat by the advancing/retreating mechanism 134.

The base 131 is formed in a rectangular shape elongated in the Y-axis direction when viewed in a plane, and allows the moving body 132 thereon to move in the Y-axis direction. For example, the base 131 has a plurality of rails (not illustrated) extending in the Y-axis direction, and moves a plurality of rolling bodies (not illustrated) provided on a lower surface of the moving body 132 along the rails.

The moving body 132 has an internal horizontal drive unit that rotates the plurality of rolling bodies, and moves in the Y-axis direction on the base 131 based on the drive of the horizontal drive unit. The moving body 132 is positioned at a target position in the Y-axis direction based on the control of the control unit 90.

The pivot mechanism 133 is provided on the moving body 132 and turns the advancing/retreating mechanism 134. For example, the pivot mechanism 133 includes a pivot drive unit provided inside the moving body 132 and a disc that is fixed to the advancing/retreating mechanism 134 and rotates by the pivot drive unit. The pivot mechanism 133 is positioned at a target pivot position based on the control of the control unit 90. The target pivot position is, for example, a position where the plurality of forks 135 extend along the X-axis direction (X-axis positive direction and X-axis negative direction).

The advancing/retreating mechanism 134 includes a fixed portion fixed to the pivot mechanism 133, and an arm 134a that is capable of advancing/retreating relative to the fixed portion. The arm 134a supports the plurality of forks 135 and further allows each fork 135 to advance and retreat from the advance position of the arm 134a. In a state of being positioned at the target pivot position by the pivot mechanism 133, the advancing/retreating mechanism 134 advances/retreats each fork 135 in the X-axis direction (X-axis positive direction and X-axis negative direction) via the arm 134a.

The plurality of forks 135 (e.g., five in FIG. 3) are provided on the arm 134a. The number of forks 135 is not particularly limited. The advancing/retreating mechanism 134 may advance and retreat the plurality of forks 135 simultaneously, or may advance and retreat only one fork 135 when receiving and transferring the substrate W. For example, the advancing/retreating mechanism 134 may be configured to selectively execute a first pattern in which only one upper fork 135 is advanced/retreated, and a second pattern in which four lower forks 135 are advanced/retreated simultaneously. Inside the arm 134a, a gap adjustment mechanism may be provided to adjust a vertical gap between the forks 135.

The fork 135 includes a root 135a fixed to the arm 134a, and a pair of claws 135b protruding from the root 135a in a tip direction. As a result, the fork 135 is formed in a U-shape in a plan view, and has an opening that is open in the tip direction. The root 135a and the pair of claws 135b are formed of a single plate and are coplanar. The root 135a and the pair of claws 135b are set to have a size corresponding to the diameter of the substrate W, and transfer the substrate W placed thereon.

The fork 135 may have a plurality of (e.g., three) suction pads 135c on its upper surface. The suction pads 135c are disposed near a tip of the root 135a adjacent to the opening and near tips of the claws 135b so as to face the outer periphery of the substrate W. The suction pads 135c communicate with flow paths respectively provided in the root 135a and the claws 135b, and the flow paths are connected to a suction device (not illustrated). The suction device applies a suction force to the respective suction pads 135c under the control of the control unit 90, thereby suctioning the substrate W placed on the suction pads 135c. Holding the substrate W by the fork 135 is not limited to suction by suction force, and may employ electrostatic suction or a mechanical fixing mechanism.

In addition, the fork 135 includes a detection sensor 136 at the tip of the pair of claws 135b to detect an object and recognizing its position. The control unit 90 moves the transfer device 130 while monitoring the position (three-dimensional coordinates) of the detection sensor 136 in the loading region 102, and detects an object in the loading region 102 by the detection sensor 136. For example, the detection sensor 136 detects the presence or absence of a detection target (not illustrated) provided at the position of the wafer boat 20 for transferring and receiving the substrate W, and transmits the detection result to the control unit 90. The control unit 90 may instruct the wafer boat 20 on the positions for transferring and receiving the substrate W by linking the three-dimensional coordinates mapped in accordance with the movement of the transfer device 130 with information on the presence of the detection target.

The detection sensor 136 according to an embodiment includes, for example, a light projecting unit 136a and a light receiving unit 136b, which are arranged to face each other in the horizontal direction. The light projecting unit 136a is provided at the tip of one of the pair of claws 135b, and irradiates a detection light toward the light receiving unit 136b. The light receiving unit 136b is provided at the tip of the other of the pair of claws 135b, and receives the detection light irradiated by the light projecting unit 136a. When an object is present between the light projecting unit 136a and the light receiving unit 136b, the light receiving unit 136b transmits information to the control unit 90, indicating that the detection light irradiated by the light projecting unit 136a is blocked (non-detection information). As a result, the control unit 90 recognizes, as the position of the object, three-dimensional coordinates at the time when the information is received.

In addition, the transfer device 130 includes a lifting mechanism 137 that raises and lowers each fork 135 in the vertical direction within the loading region 102. The lifting mechanism 137 may have an appropriate configuration, and may be, for example, a ball screw mechanism or a rack-pinion gear mechanism. The lifting mechanism 137 includes a guide body 137a that extends vertically within the loading region 102, and a lifting drive unit 137b that raises and lowers the transfer device 130 in the vertical direction while being guided by the guide body 137a.

The guide body 137a extends long in the vertical direction within the loading region 102 to enable the transfer device 130 to transfer each substrate W to and from the wafer boat 20 which is elongated in the vertical direction. For example, both ends of the guide body 137a are fixed to the ceiling and floor of the loading region 102, respectively.

The lifting drive unit 137b moves each fork 135 parallel to the vertical direction (longitudinal direction) of the wafer boat 20 by lifting or lowering along the guide body 137a. The lifting drive unit 137b is connected to the control unit 90 and positions each fork 135 at a target lifting/lowering position under the control of the control unit 90. In FIG. 3, the lifting drive unit 137b is fixed to one side of the base 131 and is configured to lift/lower the base 131 and the mechanism thereon as a whole. However, the lifting drive unit 137b is not limited to this configuration. The lifting drive unit 137b may be configured to lift/lower the base 131 by rotatably supporting the guide body 137a at an end of the guide body 137a.

The transfer device 130 is not limited to the above-described configuration, and may be any of various devices capable of transporting the substrate W. For example, the transfer device 130 may be a multi-joint device having multiple arms and multiple joints to move the fork.

Referring back to FIG. 1, the reference member 140 in the loading region 102 is a member used as an index when monitoring the state of the guide body 137a of the transfer device 130. The reference member 140 will be described in detail later.

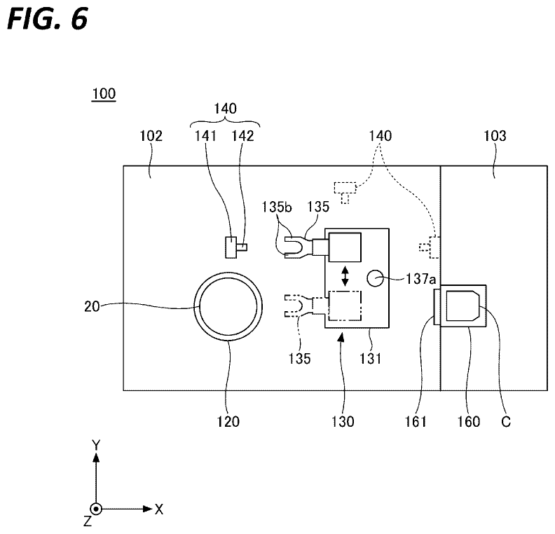

The carrying-in/out region 103 of the heat treatment system 100 is provided adjacent to the loading region 102. For example, the carrying-in/out region 103 may conform to the Front-opening Interface Mechanical Standards (FIMS) system, which is a mechanical standard. The loading region 102 and the carrying-in/out region 103 are partitioned by a partition wall 104. The carrying-in/out region 103 has a mounting table 160 provided at a position corresponding to a port 161 (see, e.g., FIG. 6) provided in the partition wall 104, allowing the container C to be set thereon. The port 161 is configured to be openable and closable between the loading region 102 and the carrying-in/out region 103, and exposes the container C set on the mounting table 160 to the loading region 102 in an open state.

In the carrying-in/out region 103, there is a storage mechanism that has a plurality of containers C waiting, for example, in the vertical direction. The storage mechanism may transport the stored container C and set it on the mounting table 160. The storage mechanism also has a load port (not illustrated) through which the containers C are carried into and from the carrying-in/out region 103.

In the above-described heat treatment system 100, after heat treatment in the processing region 101, the wafer boat 20 carrying high-temperature substrates W is unloaded into the loading region 102, causing a rise in temperature in the loading region 102. As described above, the guide body 137a extends long in the vertical direction of the loading region 102. In this case, the guide body 137a may be deformed due to a difference in thermal expansion caused by a rise in temperature in the loading region 102.

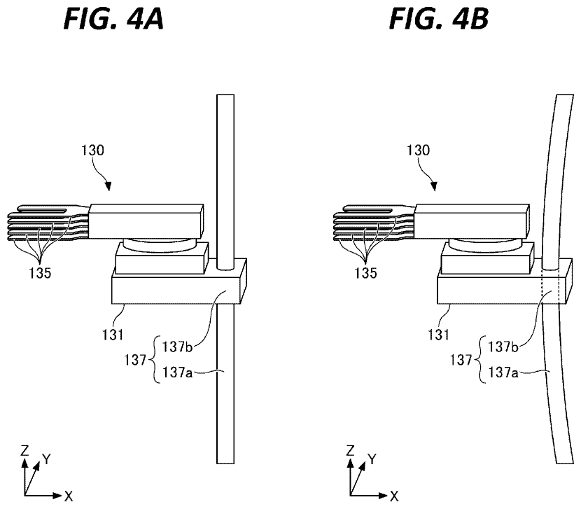

For example, the control unit 90 of the heat treatment system 100 instructs the transfer device 130 on the positions (three-dimensional coordinates) for transferring and receiving the substrate W with respect to the wafer boat 20 at room temperature before the operation of the heat treatment device 1. At this time, the guide body 137a extends linearly along the vertical direction because it is not thermally expanded as illustrated in FIG. 4A. Therefore, the transfer device 130 may stably rise and fall in the vertical direction. For the instructed positions for transferring and receiving each substrate W with respect to the wafer boat 20, the control unit 90 recognizes values at which the X-axis coordinates and Y-axis coordinates become approximately constant along the vertical direction.

In the meantime, in the loading region 102 of the heat treatment system 100, the temperature in the space rises due to the thermal effect of each substrate W after heat treatment, and thus the guide body 137a thermally expands and deforms as illustrated in FIG. 4B. In this case, deformation occurs in a structural basis supporting each fork 135, and the entire transfer device 130 is affected by the deformation. For example, the transfer device 130 may transfer and receive the substrate W in an inclined position (facing up or down) relative to the wafer boat 20.

Particularly, in a configuration having the base 131, the moving body 132, the pivot mechanism 133, the advancing/retreating mechanism 134, and the forks 135 in the X-axis direction with respect to the guide body 137a, the guide body 137a receives loads in the X-axis direction from such components, and is therefore prone to deformation along the X-axis direction. However, the degree of deformation of the guide body 137a (such as the amount of deformation or the shape of deformation) is difficult to predict because it is also affected by temperature, the position of the transfer device 130, and the like. Furthermore, in the heat treatment system 100, heat is accumulated in the loading region 102 as a result of multiple heat treatments, and thus the degree of deformation of the guide body 137a may vary depending on the number of heat treatments.

Therefore, the heat treatment system 100 according to an embodiment is configured to install the reference member 140 within the movement range of the fork 135 of the transfer device 130, and recognize the degree of deformation of the guide body 137a of the transfer device 130 relative to the reference member 140. This enables the heat treatment system 100 to take various measures in response to the degree of deformation of the guide body 137a.

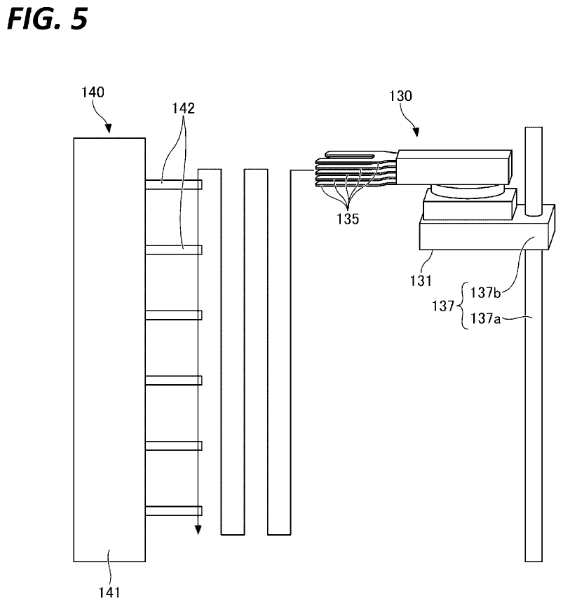

As illustrated in FIG. 5, the reference member 140 includes a base body 141 extending in the vertical direction, and a plurality of protrusions 142 protruding laterally from the base body 141. The plurality of protrusions 142 are arranged at regular intervals along the vertical direction (a direction parallel to the longitudinal direction of the wafer boat 20). Although the protrusions 142 may have three or more protrusions (located at top, bottom, and middle position(s)), the number of protrusions is not particularly limited. The base body 141 and the plurality of protrusions 142 may be made of a material having a small thermal expansion coefficient, such as quartz, stainless steel, silicon carbide, silicon nitride, and low thermal expansion metal (Invar).

In order to increase rigidity, the base body 141 is formed in a columnar shape that is larger (or thicker) than the guide body 137a. The protruding lengths of the protrusions 142 from the base body 141 are set to be all constant. The protruding lengths of the protrusions 142 are not particularly limited as long as the forks 135 of the transfer device 130 may reach them. In addition, each protrusion 142 is formed with a size (thickness) that allows it to enter between the pair of claws 135b of the transfer device 130 (the fork 135).

Each protrusion 142 is provided at a height position at least corresponding to the wafer boat 20 placed on the boat stage 120. For example, the uppermost protrusion 142 among the protrusions 142 is installed to be positioned vertically above the uppermost substrate W among the substrates W in the wafer boat 20. Similarly, the lowermost protrusion 142 among the protrusions 142 is installed to be positioned vertically below the lowermost substrate W among the substrates W in the wafer boat 20.

When checking the deformation of the guide body 137a, the control unit 90 moves the transfer device 130 to a position where the fork 135 faces the reference member 140. The control unit 90 then operates the transfer device 130 such that the transfer device 130 gradually approaches each of the protrusions 142 while repeatedly ascending and descending. When the detection sensor 136 of the fork 135 detects protruding ends of the respective protrusions 142, the control unit 90 maps the three-dimensional coordinates. This enables the control unit 90 to plot (grasp) the shape of the guide body 137a based on the positions of the protruding ends of the respective protrusions 142 of the reference member 140.

Specifically, the control unit 90 performs detection with the detection sensor 136 while repeating the following operations (a) to (d) by controlling the transfer device 130.
(a) sliding the fork 135 along the horizontal direction by a certain horizontal pitch (e.g., 0.1 mm) at the first height position, thereby approaching the protrusion 142.
(b) lowing the fork 135 along the vertical direction by a certain vertical length from the first height position, thereby being disposed at the second height position.
(c) sliding the fork 135 along the horizontal direction by a certain horizontal pitch at the second height position, thereby approaching the protrusion 142.
(d) raising the fork 135 along the vertical direction by a certain vertical length from the second height position, thereby being disposed at the first height position.

In the above operations, the first height position and the second height position are set in a range greater than the vertical length of the wafer boat 20 placed on the boat stage 120. The horizontal pitch of the fork 135 may be set arbitrarily, and may be, for example, in the range of about 0.5 mm to 2 mm.

During the above operations (a) to (d) repeatedly performed, if the detection light irradiated from the light projecting unit 136a of the detection sensor 136 toward the light receiving unit 136b hits the protrusion 142, it is blocked. The control unit 90 maps (stores) the three-dimensional coordinates of each protrusion 142 that blocks the detection light of the detection sensor 136.

The installation position of the reference member 140 in the loading region 102 is not particularly limited as long as it is within the range where the fork 135 may reach. For example, as illustrated by the solid line in FIG. 6, the reference member 140 may be installed at a position adjacent to the boat stage 120. Alternatively, as illustrated by the dotted line in FIG. 6, the reference member 140 may be installed at a position adjacent to the port 161 in the partition wall 104. This position is opposite the wafer boat 20 across the guide body 137a, and thus is less susceptible to the heat of each substrate W. Similarly to this, the reference member 140 disposed in the X-axis direction of the transfer device 130 functions as an index for detecting deformation of the guide body 137a along the X-axis direction.

Furthermore, the reference member 140 may be disposed at a position different from the X-axis direction of the transfer device 130. For example, as illustrated by the dotted line in FIG. 6, the reference member 140 may be disposed in the Y-axis direction of the transfer device 130. This enables the control unit 90 to detect deformation of the guide body 137a in a direction (the Y-axis direction) different from the X-axis direction.

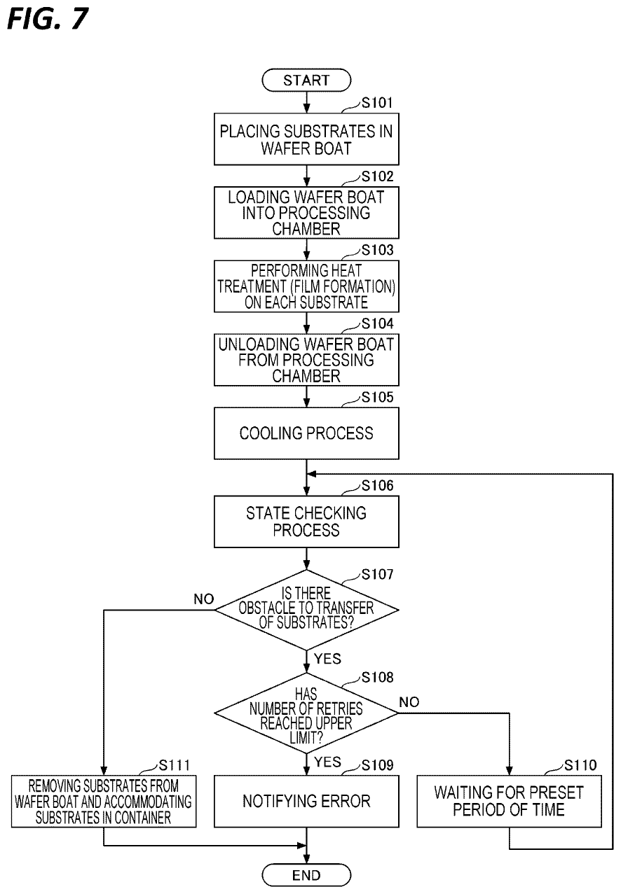

The heat treatment system 100 according to an embodiment is basically configured as described above. Hereinafter, the operation (heat treatment method including a state monitoring method) of the heat treatment system will be described with reference to the flowchart of FIG. 7.

The control unit 90 controls the respective components of the heat treatment system 100 in the heat treatment method for the plurality of substrates W, and sequentially performs steps S101 to S111 in FIG. 7. The positions for transferring and receiving the substrates W to and from the wafer boat 20, which are necessary for the transfer by the transfer device 130, and the positions for transferring and receiving the substrates W to and from the container C on the mounting table 160, etc. are instructed before the heat treatment method is performed.

The transfer device 130 operates based on instructions from the control unit 90, takes out the substrates W accommodated in the container C, and places the substrates W in the wafer boat 20 waiting on the boat stage 120 (step S101). At this time, the transfer device 130 may adopt the first pattern in which one fork 135 transfers the substrates W one by one, but it may transfer the substrates W efficiently by adopting the second pattern in which the plurality of forks 135 transfer the plurality of substrates W.

After the respective substrates W are arranged vertically in the wafer boat 20, the boat operating unit 110 raises the wafer boat 20 and loads the wafer boat 20 into the processing chamber 10 of the heat treatment apparatus 1 (step S102). After the wafer boat 20 is loaded, the heat treatment apparatus 1 closes the lower end of the manifold 17 with the lid 21.

Thereafter, the heat treatment apparatus 1 performs heat treatment (film formation process) on each substrate W in the processing chamber 10 (step S103). In the film formation process, the gas supply unit 30 supplies a process gas into the processing chamber 10, the gas exhaust unit 40 exhausts the gas in the processing chamber 10, and the temperature control furnace 50 heats each substrate W to a target temperature. As a result, a film having a desired thickness is formed on each substrate W.

After the heat treatment is completed in the heat treatment apparatus 1, the heat treatment apparatus 1 opens the lid 21, and the boat operating unit 110 lowers the wafer boat 20 to unload the wafer boat 20 from the processing chamber 10 (step S104). The unloaded wafer boat 20 is placed on the boat stage 120.

Next, the heat treatment system 100 waits for a set time to perform a cooling process to cool the wafer boat 20 and each substrate W (step S105). By performing this cooling process, the temperature of each substrate W is reduced, and the temperature in the loading region 102 is also reduced to a certain degree. The loading region 102 may include an internal cooling device that promotes a reduction in the temperature of each substrate W during cleaning or other processes.

After the cooling process, the control unit 90 performs a state checking process to check the state of the transfer device 130 (the guide body 137a), using the transfer device 130 and the reference member 140 (step S106). That is, the state checking process is performed after the heat treatment is completed by the heat treatment apparatus 1 and before the substrates W are removed from the wafer boat 20 by the transfer device 130.

In the state checking process, the transfer device 130 moves to a position facing the reference member 140 as described above, and repeats vertical lifting and lowering while enabling the fork 135 to horizontally approach the reference member 140. At this time, the transfer device 130 may move the fork 135 by adopting the first pattern in which only one fork 135 is advanced. When the fork 135 moves, the control unit 90 detects the presence or absence of the protruding end of each protrusion 142 of the reference member 140 by the detection sensor 136, thereby mapping the position of each protrusion 142. For example, if a vertical middle portion of the guide body 137a is curved toward the negative direction of the X-axis, the control unit 90 recognizes, by mapping using the detection sensor 136, the positions of the uppermost protrusion 142 and the lowermost protrusion 142, which are farther away in the negative direction of the X-axis. In the meantime, the control unit 90 recognizes the position of the vertical middle protrusion 142, which is closer to the positive direction of the X-axis. Based on these detection results, the control unit 90 may grasp (estimate) the degree of deformation of the guide body 137a.

After performing the state checking process, the control unit 90 determines whether there is an obstacle to the transfer of the substrate W (step S107). For example, the control unit 90 has a threshold for comparing the degree of deformation, and determines whether or not the degree of deformation of the guide body 137a is equal to or greater than the threshold. In the case of being equal to or greater than the threshold, the deformation of the guide body 137a may be considered as causing an obstacle to the transfer of the substrate W, and in the case of being less than the threshold, the deformation of the guide body 137a may be considered as small (or not deformed). When there is an obstacle to the transfer of the substrate W (step S107: YES), the control unit 90 proceeds to step S108, and when there is no obstacle to the transfer of the substrate W, the control unit 90 proceeds to step S111.

In step S108, the control unit 90 determines whether the number of retries of the state checking process has reached an upper limit. When the number of retries has reached the upper limit, the control unit 90 recognizes that the deformation of the guide body 137a has not been resolved even when the state checking process is performed multiple times. When the number of retries has reached the upper limit (step S108: YES), the control unit 90 proceeds to step S109, whereas when the number of retries has not reached the upper limit (step S108: NO), the control unit 90 proceeds to step S110.

In step S109, the control unit 90 recognizes that an abnormality has occurred in the transfer device 130, and notifies an error to a user via a user interface. The error may include information indicating that an abnormality has occurred in the transfer device 130, the degree of deformation of the guide body 137a, etc. Based on the content of the error, the user may determine whether to continue transfer by the transfer device 130 or stop processing, and take appropriate action. When an abnormality has occurred in the transfer device 130, the control unit 90 may automatically stop the operation of the heat treatment system 100 together with notifying the error.

In the meantime, When the number of retries has not reached the upper limit, the control unit 90 increments the number of retries for the process and waits for a preset period of time to lower the temperature in the loading region 102 (step S110). The loading region 102 may be further cooled by a cooling device during wait. When the period of time ends, the control unit 90 returns to step S106 and performs the state checking process again.

Furthermore, if there is no obstacle to the transfer of the substrates W in step S107, the transfer device 130 performs an operation of removing the substrates W from the wafer boat 20 and storing the substrates W in the container C waiting on the mounting table 160 (step S111). At this time, the transfer device 130 may stably rise and fall in the vertical direction along the guide body 137a, and may smoothly remove the substrates W from the wafer boat 20. Therefore, the transfer device 130 may store the substrates W in the container C with high accuracy.

Steps S106 to S111 of the heat treatment method correspond to the state monitoring method according to an embodiment. The state monitoring method may effectively monitor the state of the transfer device 130 by determining the degree of deformation of the guide body 137a of the transfer device 130 while using the reference member 140 installed in the loading region 102. Furthermore, the state monitoring method may suppress poor holding of the substrate W when transferring the substrate W after heat treatment, by recognizing the degree of deformation of the guide body 137a after the heat treatment of the substrate W and before transferring the substrate W.

The heat treatment system 100 is not limited to the above-described embodiment, and may have various modifications. For example, the heat treatment system 100 may perform the state checking process of the transfer device 130 even when the temperature in the loading region 102 is not high (e.g., room temperature). The deformation of the guide body 137a may also occur due to thermal contraction, aging, or other disturbances. Therefore, the heat treatment system 100 may appropriately manage the state of the transfer device 130 by performing the state checking process periodically or at any timing.

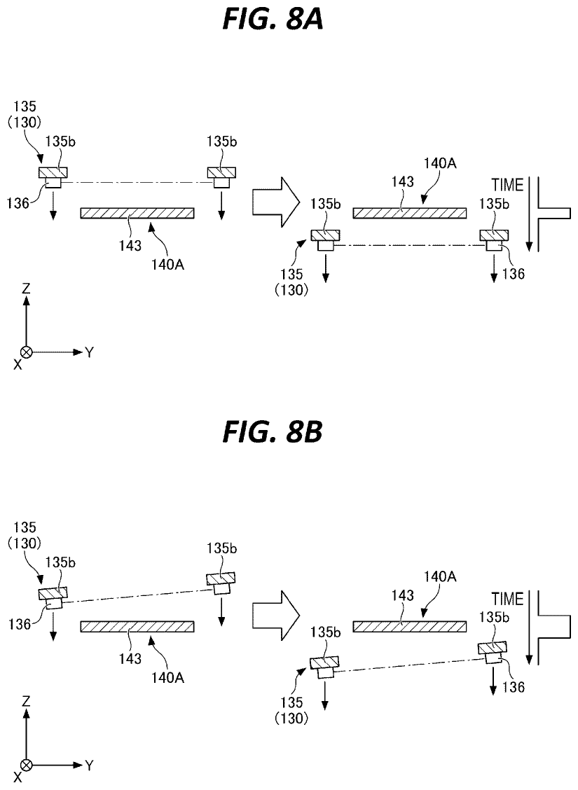

In addition, as illustrated in FIGS. 8A and 8B, the heat treatment system 100 may employ a reference member 140A having a flat protrusion 143 that extends in the horizontal direction and is configured to be detected by the detection sensor 136 of the transfer device 130. This allows the heat treatment system 100 to recognize deformation in the Y-axis direction in addition to deformation in the X-axis direction, depending on the detection time of the protrusion 143 by the detection sensor 136.

Specifically, as illustrated in FIG. 8A, when the guide body 137a is not deformed in the Y-axis direction, the claws 135b of the fork 135 of the transfer device 130 are aligned horizontally. Therefore, when the transfer device 130 is raised or lowered, the detection sensor 136 provided on the claws 135b detects the protrusion 143 in a short detection time. The control unit 90 holds, as a reference time, the detection time of the protrusion 143 when the guide body 137a is not deformed in the Y-axis direction.

In the meantime, as illustrated in FIG. 8B, when the guide body 137a is deformed in the Y-axis direction, the claws 135b of the fork 135 of the transfer device 130 are aligned in a state inclined with respect to the horizontal direction. Therefore, when the transfer device 130 is raised and lowered, the detection sensor 136 provided on the claws 135b detects the protrusion 143 in a long detection time. By comparing this detection time with the reference time, the control unit 90 may estimate the inclination of the claws 135b, in other words, the deformation state of the guide body 137a. Therefore, by performing the state checking process of the transfer device 130 with respect to one reference member 140A, the control unit 90 may simultaneously recognize both the deformation state of the guide body 137a in the X-axis direction and the deformation state of the guide body 137a in the Y-axis direction.

The technical ideas and effects of the present disclosure explained in the above embodiments will be described below.

A first aspect of the present disclosure is a heat treatment system 100 including: a substrate holder (wafer boat 20) that holds a plurality of substrates W; a transfer device 130 that is provided in a loading region 102 where the substrate holder waits and transfers the plurality of substrates W to the substrate holder; a control unit 90 that controls an operation of the transfer device 130; and a reference member 140 installed within a movement range of the transfer device 130 in the loading region 102, in which the transfer device 130 includes a guide body 137a that moves parallel to a longitudinal direction of the substrate holder, and a detection sensor 136 that detects the reference member 140, and the control unit 90 is configured to move the transfer device 130 relative to the reference member 140 and recognize a state of the guide body 137a based on detection of the reference member 140 by the detection sensor 136.

As described above, the heat treatment system 100 may effectively monitor the state of the transfer device 130 by detecting the reference member 140 with the detection sensor 136 during the movement of the transfer device 130. This allows the transfer device 130 to stably transfer the substrate W by suppressing the occurrence of an obstacle to the transfer of the substrate W due to deformation of the guide body 137a. For example, the transfer device 130 may accurately transfer and receive the substrate W to and from the substrate holder (wafer boat 20).

In addition, the heat treatment apparatus 1 accommodates the substrate holder (wafer boat 20) that holds the plurality of substrates W, and performs heat treatment on the plurality of substrates W. The control unit 90 recognizes the state of the guide body 137a after the heat treatment is performed by the heat treatment apparatus 1 and before the plurality of substrates W are removed from the substrate holder by the transfer device 130. This allows the heat treatment system 100 to reliably recognize the state of the guide body 137a before removing the substrates W after heat treatment.

In addition, the control unit 90 estimates a shape of the guide body 137a based on the detection result of the detection sensor 136 in recognizing the state of the guide body 137a, and determines whether or not there is an obstacle to the transfer of the plurality of substrates W. When there is an obstacle to the transfer of the plurality of substrates W, the control unit 90 waits for the transport of the plurality of substrates W, and when there is no obstacle to the transfer of the substrates W, the control unit 90 operates the transfer device 130 to transfer the plurality of substrates W. This allows the heat treatment system 100 to stably transfer the substrates W in a state where deformation of the guide body 137a is suppressed (or in a state where the guide body 137a is not deformed).

In addition, when moving the transfer device 130 relative to the reference member 140 to recognize the state of the guide body 137a, the control unit 90 performs detection using the detection sensor 136 while repeating operations including: sliding the transfer device 130 by a specific horizontal pitch at the first height position, lowering the transfer device 130 by a specific vertical length from the first height position to dispose the transfer device 130 at the second height position, sliding the transfer device 130 by a specific horizontal pitch at the second height position, and raising the transfer device 130 by a specific vertical length from the second height position to dispose the transfer device 130 at the first height position. This allows the control unit 90 to accurately recognize the degree of deformation of the guide body 137a by detecting the reference member 140 using the detection sensor 136.

In addition, the transfer device 130 includes the fork 135 capable of holding and transferring a substrate W at a position closer to the substrate holder (wafer boat 20) with respect to the guide body 137a, and the reference member 140 is installed at a position adjacent to the substrate holder or at a position opposite the substrate holder across the guide body 137a. Therefore, based on detection by the detection sensor 136, the heat treatment system 100 may accurately recognize the shape of the guide body 137a deformed toward or in the opposite direction to the substrate holder due to the load of the transfer device 130.

The reference member 140 includes a plurality of protrusions 142 arranged in a direction parallel to the longitudinal direction of the substrate holder (wafer boat 20). This allows the detection sensor 136 of the transfer device 130 to discretely detect the protruding ends of the protrusions 142, thereby allowing the control unit 90 to easily recognize the degree of deformation of the guide body 137a.

The reference member 140 is formed of one of quartz, stainless steel, silicon carbide, silicon nitride, and low thermal expansion metal. This material prevents the reference member 140 from being deformed by the influence of heat and allows the reference member 140 to be appropriately used for monitoring the state of the transfer device 130.

A second aspect of the present disclosure is a state monitoring method for monitoring a state of a transfer device 130 of a heat treatment system 100 that performs heat treatment on a plurality of substrates W held by a substrate holder (wafer boat 20), in which a reference member 140 is installed within a movement range of the transfer device 130 in a loading region 102 where the substrate holder waits, and the transfer device 130 includes a guide body 137a that moves parallel to a longitudinal direction of the substrate holder, and a detection sensor 136 that detects the reference member 140, and is configured to be provided in the loading region 102 and transfer the substrates W to the substrate holder. The state monitoring method includes (a) moving the transfer device 130 relative to the reference member 140 and detecting the reference member 140 by the detection sensor 136, and (b) recognizing a state of the guide body 137a based on a position where the reference member 140 is detected in (a). Even in this case, the state monitoring method may stably transfer the substrates W by monitoring the state of the transfer device 130 of the heat treatment system 100.

According to an aspect, state monitoring on the transfer device of the heat treatment system allows the substrate to be transferred stably.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A heat treatment system comprising:
a substrate holder configured to hold a plurality of substrates;
a transfer device including an arm provided in a loading region where the substrate holder waits and configured to transfer the plurality of substrates to the substrate holder;
a controller configured to control an operation of the transfer device; and
a reference body installed within a movement range of the transfer device in the loading region,
wherein the transfer device includes a guide body that moves parallel to a longitudinal direction of the substrate holder, and a detection sensor that detects the reference body, and
the controller is configured to move the transfer device relative to the reference body and recognize a state of the guide body based on detection of the reference body by the detection sensor.

2. The heat treatment system according to claim 1, further comprising:
a heat treatment apparatus configured to accommodate the substrate holder that holds the plurality of substrates, and perform heat treatment on the plurality of substrates,
wherein the controller recognizes the state of the guide body after the heat treatment is performed by the heat treatment apparatus and before the plurality of substrates are removed from the substrate holder by the transfer device.

3. The heat treatment system according to claim 2, wherein the controller estimates a shape of the guide body based on the detection result of the detection sensor in recognizing the state of the guide body, and determines whether or not there is an obstacle to the transfer of the plurality of substrates,
when there is an obstacle to the transfer of the plurality of substrates, the controller waits for the transfer of the plurality of substrates, and
when there is no obstacle to the transfer of the plurality of substrates, the controller operates the transfer device to transfer the plurality of substrates.

4. The heat treatment system according to claim 1, wherein
when moving the transfer device relative to the reference member to recognize the state of the guide body, the controller performs detection using the detection sensor while repeating operations including: sliding the transfer device by a specific horizontal pitch at a first height position, lowering the transfer device by a specific vertical length from the first height position to dispose the transfer device at a second height position, sliding the transfer device by a specific horizontal pitch at the second height position, and raising the transfer device by a specific vertical length from the second height position to dispose the transfer device at the first height position.

5. The heat treatment system according to claim 1, wherein
the transfer device includes a fork capable of holding and transferring a substrate at a position closer to the substrate holder with respect to the guide body, and
the reference body is installed at a position adjacent to the substrate holder or at a position opposite the substrate holder across the guide body.

6. The heat treatment system according to claim 1, wherein the reference body includes a plurality of protrusions arranged in a direction parallel to the longitudinal direction of the substrate holder.

7. The heat treatment system according to claim 1, wherein the reference body is formed of one of quartz, stainless steel, silicon carbide, silicon nitride, and a low-thermal-expansion metal.

8. A state monitoring method comprising:
providing a heat treatment system including:
a substrate holder configured to hold a plurality of substrates;
a transfer device including an arm provided in a loading region where the substrate holder waits and configured to transfer the plurality of substrates to the substrate holder; and
a reference body installed within a movement range of the transfer device in the loading region,
wherein the transfer device includes a guide body that moves in parallel with a longitudinal direction of the substrate holder, and a detection sensor that detects the reference body;
moving the transfer device relative to the reference body, thereby detecting the reference body by the detection sensor, and
recognizing a state of the guide body based on a position where the reference body is detected in the moving.
